(19) United States
(12) Patent Application Publication
(10) Pub. No.: US 2026/0357114 A1
(43) Pub. Date: Nov. 12, 2026

(54) PRESSURE-SENSITIVE ADHESIVE SHEET FOR SEMICONDUCTOR PROCESSING WITH RELEASE LINER

(71) Applicant: NITTO DENKO CORPORATION, Osaka (JP)

(72) Inventor: Yuji OKAWA, Ibaraki-shi (JP)

(21) Appl. No.: 19/669,028

(22) Filed: May 6, 2026

(30) Foreign Application Priority Data
May 12, 2025 (JP) 2025-079856

(51) Int. Cl. C09J 7/40; C09J 7/38; H10P 72/70

(52) U.S. Cl. CPC C09J 7/401; C09J 7/38; H10P 72/7404; C09J 2203/326; C09J 2301/302; C09J 2479/025; C09J 2483/00

(57) ABSTRACT

Provided is a pressure-sensitive adhesive sheet for semiconductor processing with a release liner, which can maintain easy peelability between its pressure-sensitive adhesive layer and release treatment layer, and a predetermined peel strength. The pressure-sensitive adhesive sheet for semiconductor processing with a release liner includes: a pressure-sensitive adhesive sheet including a substrate and a pressure-sensitive adhesive layer; a release-treated layer laminated on the pressure-sensitive adhesive layer; and a support for the release-treated layer. The release-treated layer is one of (A) a layer formed by using a composition containing 0.1 part by weight to 2.0 parts by weight of a silicone-based release treatment agent with respect to 100 parts by weight of a melamine resin, or (B) a layer formed by using a composition containing a melamine resin and a long-chain alkyl-based release treatment agent.

This application claims priority under 35 U.S.C. Section 119 to Japanese Patent Application No. 2025-079856 filed on May 12, 2025, which is herein incorporated by reference.

### BACKGROUND OF THE INVENTION

### Field of the Invention

The present invention relates to a pressure-sensitive adhesive sheet for semiconductor processing with a release liner.

### Description of the Related Art

A pressure-sensitive adhesive sheet has been used for various purposes, such as the fixation of an adherend and surface protection. For example, there has been known a pressure-sensitive adhesive tape for resin encapsulation to be used in an encapsulation step, in which an encapsulating resin is used, in a production process for a semiconductor apparatus (Japanese Patent No. 5551568). In the pressure-sensitive adhesive sheet, a release liner is laminated on a pressure-sensitive adhesive layer to protect the pressure-sensitive adhesive layer until the sheet is used (Japanese Patent Application Laid-open No. 2020-2203). A release treatment agent is used in the release-treated layer of the release liner to improve its peel strength. A fluorine-based release treatment agent has been known as the release treatment agent. The fluorine-based release treatment agent can exhibit easy peelability even on a pressure-sensitive adhesive layer having a large pressure-sensitive adhesive strength. However, an environmental problem due to organofluorine compounds (PFAS) has been attracting attention in recent years, and hence regulations on the use of fluorine-based compounds have been tightened.

### SUMMARY OF THE INVENTION

A long-chain alkyl-based release treatment agent and a silicone-based release treatment agent have been known as non-fluorine-based release treatment agents. When the long-chain alkyl-based release treatment agent is stored for a long time period, its peel strength may reduce to make the release liner hardly peelable. In addition, at the time of the peeling of the release liner, a component in the release-treated layer may migrate to the pressure-sensitive adhesive layer. When the release treatment agent migrates to the pressure-sensitive adhesive layer, the release treatment agent may adhere to the surface of an adherend having bonded thereto the pressure-sensitive adhesive layer. When the component in the release treatment layer adheres thereto, in the case where an encapsulating resin or an adhesion layer is arranged on the adherend in a step after the peeling of the pressure-sensitive adhesive sheet, the encapsulating resin or the adhesion layer may peel under a high-temperature and high-humidity environment to reduce the reliability of a final product. In addition, when the adherend to which the release treatment agent has adhered is subjected to a step of bringing the adherend into contact with a liquid treatment agent, the liquid treatment agent may be repelled by the surface of the adherend to make it impossible to perform a predetermined step. Accordingly, there has been demanded a pressure-sensitive adhesive sheet including a release liner, which can maintain easy peelability between its pressure-sensitive adhesive layer and release treatment layer, and a predetermined peel strength.
1. According to at least one embodiment of the present invention, there is provided a pressure-sensitive adhesive sheet for semiconductor processing with a release liner, including: a pressure-sensitive adhesive sheet including a substrate and a pressure-sensitive adhesive a release-treated layer layer; laminated on the pressure-sensitive adhesive layer; and a support for the release-treated layer, wherein the release-treated layer is one of (A) a layer formed by using a composition containing 0.1 part by weight to 2.0 parts by weight of a silicone-based release treatment agent with respect to 100 parts by weight of a melamine resin, or (B) a layer formed by using a composition containing a melamine resin and a long-chain alkyl-based release treatment agent.
2. In the pressure-sensitive adhesive sheet for semiconductor processing with a release liner according to the above-mentioned item 1, the silicone-based release treatment agent may be a straight silicone oil.
3. In the pressure-sensitive adhesive sheet for semiconductor processing with a release liner according to the above-mentioned item 1 or 2, the pressure-sensitive adhesive layer may contain a silicone-based pressure-sensitive adhesive.
4. In the pressure-sensitive adhesive sheet for semiconductor processing with a release liner according to any one of the above-mentioned items 1 to 3, a surface of the release-treated layer peeled from the pressure-sensitive adhesive layer may have a surface free energy of from 10 dyn/cm to 22.5 dyn/cm.
5. In the pressure-sensitive adhesive sheet for semiconductor processing with a release liner according to any one of the above-mentioned items 1 to 4, a Si amount on a surface of the release-treated layer peeled from the pressure-sensitive adhesive layer, which is measured by X-ray photoelectron spectroscopy, may be 1.0 atomic or less.
6. In the pressure-sensitive adhesive sheet for semiconductor processing with a release liner according to the above-mentioned item 1, the long-chain alkyl-based release treatment agent may be a long-chain alkyl group-containing compound having an alkyl group having 8 to 22 carbon atoms.
7. In the pressure-sensitive adhesive sheet for semiconductor processing with a release liner according to any one of the above-mentioned items 1 to 6, the long-chain alkyl-based release treatment agent may be a polyvinyl alcohol-based resin having a long-chain alkyl group in a side chain thereof.
8. In the pressure-sensitive adhesive sheet for semiconductor processing with a release liner according to any one of the above-mentioned items 1 to 7, the pressure-sensitive adhesive layer from which the release-treated layer has been peeled may have a pressure-sensitive adhesive strength of 1.0 N/20 mm or less.
9. In the pressure-sensitive adhesive sheet for semiconductor processing with a release liner according to any one of the above-mentioned items 1 to 8, the pressure-sensitive adhesive sheet for semiconductor processing with a release liner may have a liner peel strength of 0.5 N/50 mm or less before being heated, and the pressure-sensitive adhesive sheet for semiconductor processing with a release liner may have a liner peel strength of 1.0 N/50 mm or less after having been heated at 60 °C for 7 days.
10. The pressure-sensitive adhesive sheet for semiconductor processing with a release liner according to any one of the above-mentioned items 1 to 9 may be used in a resin encapsulation step.
11. In the pressure-sensitive adhesive sheet for semiconductor processing with a release liner according to the above-mentioned item 10, the pressure-sensitive adhesive sheet for semiconductor processing with a release liner may have a liner peel strength of 0.20 N/50 mm or less before being heated, and the pressure-sensitive adhesive sheet for semiconductor processing with a release liner may have a liner peel strength of 0.30 N/50 mm or less after having been heated at 60 °C for 7 days.

### BRIEF DESCRIPTION OF THE DRAWINGS

FIG. 1 is a schematic sectional view of a pressure-sensitive adhesive sheet for semiconductor processing with a release liner according to at least one embodiment of the present invention.

FIG. 2 is a schematic sectional view of a pressure-sensitive adhesive sheet for semiconductor processing with a release liner according to at least one embodiment of the present invention.

### DESCRIPTION OF THE EMBODIMENTS

A. Overall Configuration of Pressure-sensitive Adhesive Sheet for Semiconductor Processing with Release Liner

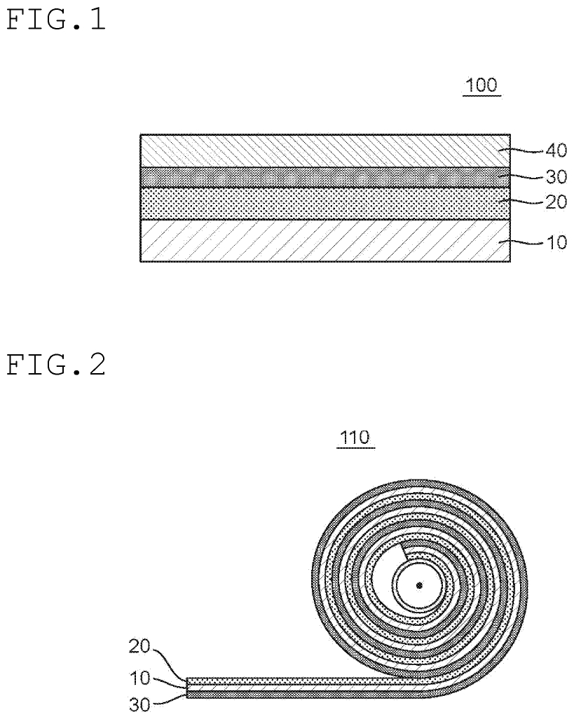

A pressure-sensitive adhesive sheet for semiconductor processing with a release liner according to at least one embodiment of the present invention (hereinafter also referred to as “pressure-sensitive adhesive sheet according to at least one embodiment of the present invention”) includes: a pressure-sensitive adhesive sheet including a substrate and a pressure-sensitive adhesive layer; a release-treated layer laminated on the pressure-sensitive adhesive layer; and a support for the release-treated layer. FIG. 1 is a schematic sectional view of a pressure-sensitive adhesive sheet for semiconductor processing with a release liner according to at least one embodiment of the present invention. The pressure-sensitive adhesive sheet of the illustrated example has a sheet shape. A pressure-sensitive adhesive sheet 100 for semiconductor processing with a release liner includes: a pressure-sensitive adhesive sheet including a substrate 10 and a pressure-sensitive adhesive layer 20; a release-treated layer 30; and a support 40. The pressure-sensitive adhesive layer 20 and the release-treated layer 30 are placed under a state in which the layers are bonded to each other until the pressure-sensitive adhesive sheet is used. At the time of the use of the pressure-sensitive adhesive sheet, the release-treated layer 30 and the support 40 are removed from the pressure-sensitive adhesive layer 20. FIG. 2 is a schematic sectional view of a pressure-sensitive adhesive sheet for semiconductor processing with a release liner according to at least one embodiment of the present invention. In the illustrated example, a pressure-sensitive adhesive sheet 110 for semiconductor processing with a release liner has a roll shape. In the pressure-sensitive adhesive sheet 110 for semiconductor processing with a release liner, the release-treated layer 30 is formed on the surface of the substrate 10 on which the pressure-sensitive adhesive layer 20 is not formed. In the illustrated example, the substrate 10 can also function as a support for the release-treated layer 30. In this embodiment, when a pressure-sensitive adhesive sheet including the substrate 10 and the pressure-sensitive adhesive layer 20 is drawn from the pressure-sensitive adhesive sheet 110 having a roll shape, the release-treated layer 30 formed on the back surface of the substrate 10 and the pressure-sensitive adhesive layer 20 are peeled from each other, and hence the pressure-sensitive adhesive sheet including the substrate 10 and the pressure-sensitive adhesive layer 20 is put into use.

The above-mentioned release-treated layer is (A) a layer (hereinafter also referred to as “release-treated layer A”) formed by using a composition containing 0.1 part by weight to 2 parts by weight of a silicone-based release treatment agent with respect to 100 parts by weight of a melamine resin,) a layer (hereinafter also referred to as “release-treated layer B”) formed by using a composition containing a melamine resin and a long-chain alkyl-based release treatment agent. The release-treated layer A and the release-treated layer B each contain the melamine resin. The melamine a resin obtained by the polycondensation of melamine and formaldehyde, and has a network cross-linked structure. Accordingly, even when the release-treated layer is stored for a long time period, the migration of the melamine resin in the release-treated layer to the pressure-sensitive adhesive layer hardly occurs, and hence easy peelability between the layers can be maintained. When a relatively small amount of the silicone-based release treatment agent or the long-chain alkyl-based release treatment agent is used in combination with the melamine resin, the release-treated layer can maintain a predetermined peel strength, and can be smoothly peeled even when stored for a long time period. In addition, the migration of a component such as the release treatment agent from the release-treated layer to the pressure-sensitive adhesive layer can be suppressed. The release treatment agent that has migrated to the surface of the pressure-sensitive adhesive layer may adhere to the adherend of the pressure-sensitive adhesive sheet. The release treatment agent that has adhered to the surface of the adherend may not only contaminate the surface but also, for example, repel a liquid treatment agent in a step in which the liquid treatment agent is used to reduce the working efficiency of the step. The pressure-sensitive adhesive sheet according to at least one embodiment of the present invention can suppress such inconvenience. Further, none of the release-treated layer A and the release-treated layer B uses a fluorine-containing release treatment agent such as a fluorosilicone-based release treatment agent. Accordingly, the occurrence of, for example, environmental pollution due to PFAS can be suppressed.

The pressure-sensitive adhesive strength of the pressure-sensitive adhesive layer after the peeling of the above-mentioned release-treated layer (hereinafter also referred to as “post-peeling pressure-sensitive adhesive strength”) is preferably 1.0 N/20 mm or less, more preferably 0.8 N/20 mm or less, still more preferably 0.7 N/20 mm or less, particularly preferably 0.62 N/20 mm or less. When the post-peeling pressure-sensitive adhesive strength falls within the above-mentioned ranges, the pressure-sensitive adhesive sheet can be suitably used in semiconductor processing applications. The post-peeling pressure-sensitive adhesive strength is, for example, 0.1 N/20 mm or more. The term “post-peeling pressure-sensitive adhesive strength” as used herein refers to a value measured by the following method.

### <Post-Peeling Pressure-Sensitive Adhesive Strength>

The pressure-sensitive adhesive sheet for semiconductor processing with a release liner is cut into a width of 20 mm to provide a sample. The release-treated layer and the support are peeled from the sample. Further, a surface of a SUS plate is washed with toluene, and is then washed with methanol. The SUS plate after the washing and the pressure-sensitive adhesive layer are bonded to each other, and are stored at room temperature for 30 minutes. After that, the resultant is subjected to a 180° peel test at a peel rate of 300 mm/min, and the resultant value is defined as a post-peeling pressure-sensitive adhesive strength.

A peel strength (hereinafter also referred to as “liner peel strength”) required at the time of the peeling of the release-treated layer and the pressure-sensitive adhesive layer from each other is preferably 0.5 N/50 mm or less, more preferably 0.3 N/50 mm or less, still more preferably 0.1 N/50 mm or less, particularly preferably 0.07 N/50 mm or less. When the liner peel strength falls within the above-mentioned ranges, the release-treated layer and the pressure-sensitive adhesive layer can be smoothly peeled from each other. The liner peel strength is preferably as low as possible, and is, for example, 0.01 N/50 mm or more. The term “liner peel strength” as used herein refers to a value measured by the following method.

### <Liner Peel Strength>

The pressure-sensitive adhesive sheet for semiconductor processing with a release liner is cut into a width of 50 mm to provide a sample. The substrate and the pressure-sensitive adhesive layer are fixed with a chuck, and the release-treated layer and the support are subjected to a 180° peel test at a peel rate of 300 mm/min. The resultant value is defined as a liner peel strength.

The liner peel strength of the pressure-sensitive adhesive sheet for semiconductor processing with a release liner after its heating at 60 °C for 7 days (hereinafter also referred to as “post-heating liner peel strength”) is preferably 1.0 N/50 mm or less, more preferably 0.7 N/50 mm or less, still more preferably 0.5 N/50 mm or less, particularly preferably 0.1 N/50 mm or less. When the post-heating liner peel strength falls within the above-mentioned ranges, even in the case where the pressure-sensitive adhesive sheet is stored for a long time period, the release-treated layer and the pressure-sensitive adhesive layer can be smoothly peeled from each other. The post-heating liner peel strength is preferably as low as possible, and is, for example, 0.02 N/50 mm or more. The term “post-heating liner peel strength” as used herein refers to a liner peel strength measured as follows: the pressure-sensitive adhesive sheet for semiconductor processing with a release liner, which has been cut into a width of 50 mm, is heated at 60 °C for 7 days with any appropriate thermostat, and is then cooled to room temperature, followed by the measurement of its liner peel strength by the above-mentioned method.

The total thickness of the pressure-sensitive adhesive sheet for semiconductor processing with a release liner according to at least one embodiment of the present invention may be set to any appropriate thickness.

The pressure-sensitive adhesive sheet for semiconductor processing with a release liner according to at least one embodiment of the present invention is specifically described below.

### B. Pressure-Sensitive Adhesive Sheet

The pressure-sensitive adhesive sheet for semiconductor processing with a release liner according to at least one embodiment of the present invention includes: the pressure-sensitive adhesive sheet including the substrate and the pressure-sensitive adhesive layer; and the release-treated layer and the support (a laminate of these layers is hereinafter also referred to as “release liner”). Any appropriate pressure-sensitive adhesive sheet may be used as the above-mentioned pressure-sensitive adhesive sheet. As described above, the pressure-sensitive adhesive sheet according to at least one embodiment of the present invention can maintain easy peelability between the pressure-sensitive adhesive layer and the release-treated layer, and a predetermined peel strength. Accordingly, the pressure-sensitive adhesive sheet may be suitably used in combination with a pressure-sensitive adhesive having a relatively high pressure-sensitive adhesive strength such as a silicone-based pressure-sensitive adhesive.

The pressure-sensitive adhesive sheet may further include any appropriate layer except the substrate and the pressure-sensitive adhesive layer. For example, an intermediate layer may be formed between the substrate and the pressure-sensitive adhesive layer.

The thickness of the pressure-sensitive adhesive sheet may be set to any appropriate range. The thickness is preferably from 10 μm to 500 μm, more preferably from 20 μm to 400 μm, still more preferably from 30 μm to 300 μm.

### B-1. Substrate

The substrate may include any appropriate resin. Specific examples of the resin for forming the substrate include polyester-based such as resins, polyethylene terephthalate (PET), polyethylene naphthalate (PEN), polybutylene terephthalate (PBT), and polybutylene naphthalate (PBN), polyolefin-based resins, such as an ethylene-vinyl acetate copolymer, an ethylene-methyl methacrylate copolymer, polyethylene, polypropylene, and an ethylene-propylene copolymer, polyvinyl alcohol, polyvinylidene chloride, polyvinyl chloride, a vinyl chloride-vinyl acetate copolymer, polyvinyl acetate, polyamide, polyimide, celluloses, a fluorine-based resin, polyether, polystyrene-based resins such as polystyrene, polycarbonate, and polyether sulfone.

The substrate may further include any other component to the extent that the effects of the present invention are not impaired. Examples of the other component include an antistatic agent, an antioxidant, a UV absorber, a light stabilizer, and a heat stabilizer. The kind and usage amount of the other component may be set appropriately in accordance with purposes.

The substrate may further include any appropriate other layer. Specific examples thereof include an easy-adhesion layer and an antistatic layer.

The thickness of the substrate may be set to any appropriate value. The thickness of the substrate is preferably from 10 μm to 250 μm, more preferably from 18 μm to 210 μm.

In at least one embodiment of the present invention, the substrate may function as a support for the release-treated layer. In this embodiment, the release-treated layer may be formed on the surface of the substrate on which the pressure-sensitive adhesive layer is not formed.

### B-2. Pressure-Sensitive Adhesive

Any appropriate pressure-sensitive adhesive is used as the pressure-sensitive adhesive. Examples thereof include an acrylic pressure-sensitive adhesive, a silicone-based pressure-sensitive adhesive, a rubber-based pressure-sensitive adhesive, a polyester-based pressure-sensitive adhesive, a urethane-based pressure-sensitive adhesive, a polyether-based pressure-sensitive adhesive, a polyamide-based pressure-sensitive adhesive, a fluorine-based pressure-sensitive adhesive, and a styrene-based pressure-sensitive adhesive. An active energy ray-curable pressure-sensitive adhesive may be used as the pressure-sensitive adhesive. When the active energy ray-curable pressure-sensitive adhesive is used, a pressure-sensitive adhesive containing a base polymer having a side chain having 8 or more carbon atoms is preferred. The pressure-sensitive adhesives may be used alone or in combination thereof.

The pressure-sensitive adhesive may contain any appropriate additive as required. Examples of the additive include a cross-linking agent, a catalyst (e.g., a platinum catalyst), a tackifier, a plasticizer, a pigment, a dye, a filler, an age resistor, a conductive material, a UV absorber, a light stabilizer, a peeling modifier, a softener, a surfactant, a flame retardant, and a solvent. The additive is used in any appropriate amount in accordance with purposes. When the pressure-sensitive adhesive is an active energy ray-curable pressure-sensitive adhesive, the pressure-sensitive adhesive contains a photopolymerization initiator.

The thickness of the pressure-sensitive adhesive layer may be set to any appropriate value. The thickness of the pressure-sensitive adhesive layer is preferably from 1 μm to 70 μm, more preferably from 2 μm to 60 μm, still more preferably from 5 μm to 50 μm. When the thickness of the pressure-sensitive adhesive layer falls within the above-mentioned ranges, a sufficient pressure-sensitive adhesive strength to an adherend can be exhibited.

C. Pressure-Sensitive Adhesive Sheet for Semiconductor Processing with Release Liner

The pressure-sensitive adhesive sheet for semiconductor processing with a release liner according to at least one embodiment of the present invention includes any appropriate pressure-sensitive adhesive sheet, and the release-treated layer A or the release-treated layer B. Embodiments in which the respective release-treated layers are used are specifically described.

C-1. Pressure-sensitive Adhesive Sheet for Semiconductor Processing with Release Liner including Release-treated Layer A

As described above, the release-treated layer A is a layer formed by using the composition containing 0.1 part by weight to 2.0 parts by weight of the silicone-based release treatment agent with respect to 100 parts by weight of the melamine resin. When the silicone-based release treatment agent migrates to the surface of the pressure-sensitive adhesive layer, and as a result, adheres to an adherend, in the case where the adherend is subjected to a step in which a liquid treatment agent is used, the adherend and the treatment agent may not be sufficiently brought into contact with each other. In addition, a silicon wafer may be used as a semiconductor wafer, and the contamination of the adherend with a silicone-based material is not preferred. In the release-treated layer A, the migration of the silicone-based release treatment agent to the surface of the pressure-sensitive adhesive layer can be suppressed.

In the composition for forming the release-treated layer A, the silicone-based release treatment agent is used at a content of from 0.1 part by weight to 2.0 parts by weight with respect to 100 parts by weight of the melamine resin, and its content is preferably from 0.12 part by weight to 1.8 parts by weight, more preferably from 0.15 part by weight to 1.6 parts by weight, still more preferably from 0.3 part by weight to 1.5 parts by weight. When the content of the silicone-based release treatment agent falls within the above-mentioned ranges, easy peelability between the pressure-sensitive adhesive layer and the release-treated layer, and a predetermined peel strength can be maintained. In addition, the migration of the silicone-based release treatment agent to the surface of the pressure-sensitive adhesive layer can be suppressed.

The thickness of the release-treated layer A may be set to any appropriate thickness. The thickness of the release-treated layer is, for example, 5 nm or more, preferably 10 nm or more, more preferably 20 nm or more, still more preferably 30 nm or more. In addition, the thickness of the release-treated layer is, for example, 200 nm or less, preferably 150 nm or less, more preferably 100 nm or less.

### C-1-1. Melamine Resin

For example, a methylated melamine resin, a butylated melamine resin, or a full ether-type methylated melamine resin may be used as the melamine resin. Of those, a methylated melamine resin is preferably used. The melamine resins may be used alone or in combination thereof.

A commercially available melamine resin may be used as the melamine resin. Examples thereof include: melamine resins available under the product names “ARACOAT RL900 series” and “ARACOAT RL3021” from Arakawa Chemical Industries, Ltd.; and a methylated melamine resin available under the product name “CYMEL 303 LF” from Allnex GmbH.

### C-1-2. Silicone-Based Release Treatment Agent

Any appropriate silicone compound may be used as the silicone-based release treatment agent. A silicone oil is preferably used. The silicone oil has a main skeleton formed of a siloxane bond. Examples of the silicone oil include: straight silicone oils, such as a dimethyl silicone oil, a methylphenyl silicone oil, and a dimethyl hydrogen silicone oil; and modified silicone oils each obtained by introducing any other organic group, such as a carboxyl group, an amino group, a polyether group, an acrylic group, or an epoxy group, into the side chain or terminal of polysiloxane. Of those, straight silicone oils may be preferably used, and a dimethyl silicone oil may be more preferably used. The use of the straight silicone oil can suppress an excessive increase in peel strength of the release-treated layer. A polyfunctional silicone oil is preferably used in a smaller amount because the oil tends to be integrated with the melamine resin to increase the peel strength. The silicone-based release treatment agents may be used alone or in combination thereof.

A commercial product may be used as the silicone-based release treatment agent. Examples thereof include a dimethyl silicone oil manufactured by Shin-Etsu Chemical Co., Ltd. and a straight silicone oil manufactured by Nihon-Resin Co., Ltd. The commercial product is more specifically, for example, a product available under the product name “KF-96L-2CS” from Shin-Etsu Chemical Co., Ltd.

### C-1-3. Additive

The composition for forming the release-treated layer A may contain any appropriate additive except the melamine resin and the silicone-based release treatment agent. Examples thereof include an antistatic agent, a colorant, a surfactant, a plasticizer, a tackifier, a low-molecular weight polymer, a surface lubricant, a leveling agent, an antioxidant, a corrosion inhibitor, a light stabilizer, a UV absorber, a polymerization inhibitor, and a filler. The additives may be used alone or in combination thereof. Those additives may each be used in any appropriate amount. Any one or more appropriate layers (e.g., an antistatic layer and a colored layer) may be formed between the support and the release-treated layer by using those additives.

### C-1-4. Support

Any appropriate support may be used as the support. Examples thereof include a resin film, paper, and a nonwoven fabric. Of those, a resin film is preferably used. Examples of a resin to be used in the resin film include: a polyolefin-based resin, such as polyethylene (PE), polypropylene (PP), an ethylene-propylene copolymer, or an ethylene-butene copolymer; a polyester-based resin, such as polyethylene terephthalate (PET), polyethylene naphthalate (PEN), or polybutylene terephthalate (PBT); a polyvinyl chloride-based resin; a polyvinylidene chloride-based resin; a polyvinyl alcohol-based resin; an ethylene-vinyl acetate copolymer resin; an ethylene-vinyl alcohol copolymer resin; a cellulose resin such as triacetyl cellulose; an acetate-based resin; a polycarbonate-based resin; a polyamide-based resin; and a polyimide-based resin. Of those, PET, PEN, and a polyimide-based resin are preferred. As described above, the substrate of the pressure-sensitive adhesive sheet may function as the support.

When the resin film is used as the support, the resin film may contain any appropriate additive. Examples of the additive include an antioxidant, an age resistor, a heat stabilizer, a light stabilizer, a UV absorber, a colorant, a lubricant, a filler, a plasticizer, an antistatic agent, a slip agent, and an antiblocking agent. The additives may be used alone or in combination thereof. Those additives are each used in any appropriate amount.

The thickness of the support may be set to any appropriate thickness. The thickness of the support is, for example, from 5 μm to 200 μm, preferably from 10 μm to 100 μm, more preferably from 25 μm to 75 μm. When the thickness of the support falls within the above-mentioned ranges, the release-treated layer and the pressure-sensitive adhesive layer can be smoothly peeled from each other.

C-1-5. Combination with Pressure-Sensitive Adhesive Sheet

As described above, the release-treated layer A and any appropriate pressure-sensitive adhesive sheet may be used in combination. In at least one embodiment of the present invention, the release-treated layer A is laminated on a pressure-sensitive adhesive sheet including a pressure-sensitive adhesive layer formed of a silicone-based pressure-sensitive adhesive (hereinafter also referred to as “silicone-based pressure-sensitive adhesive layer”), and the laminate is used as a pressure-sensitive adhesive sheet for semiconductor processing with a release liner. The silicone-based pressure-sensitive adhesive has a high pressure-sensitive adhesive strength, and hence a release treatment agent having a high peel strength such as a fluorosilicone release treatment agent has been used. The release-treated layer A can exhibit easy peelability with respect to the pressure-sensitive adhesive sheet including the silicone-based pressure-sensitive adhesive layer without use of any fluorosilicone release treatment agent.

In an embodiment in which the release-treated layer A and the pressure-sensitive adhesive sheet including the silicone-based pressure-sensitive adhesive layer are used in combination, the surface free energy of the surface of the release-treated layer peeled from the pressure-sensitive adhesive layer is preferably from 10 dyn/cm to 22.5 dyn/cm, more preferably from 18 dyn/cm to 22.5 dyn/cm. The term “surface free energy of the surface of the release-treated layer” as used herein refers to a value calculated by the following method.

### <Measurement of Surface Free Energy>

The produced pressure-sensitive adhesive sheet for semiconductor processing with a release liner is left to stand under the conditions of 23 °C and 50% RH for 1 day. Next, the pressure-sensitive adhesive sheet for semiconductor processing with a release liner is cut into a size measuring 5 cm by 5 cm and used as a sample. The release-treated layer and pressure-sensitive adhesive layer of the sample are peeled from each other. Distilled water is dropped onto the surface of the peeled release-treated layer of the laminate of the release-treated layer and the support, and a contact angle with water is measured with a contact angle meter (e.g., a product available under the product name “DM-300” from Kyowa Interface Science Co., Ltd.) under the following conditions. Another sample is prepared, and a contact angle with methylene iodide is measured in the same manner except that methylene iodide is used instead of distilled water. The surface free energy can be determined from the measured contact angles with analysis software (e.g., DropMaster 300 image processing-type solid-liquid interface analysis system manufactured by Kyowa Interface Science Co., Ltd.).

### (Measurement Conditions)

Test temperature and humidity: 23 °C and 50% RH
Dropping amount: 1.5 μL
Measurement time: measurement is started immediately after a droplet has reached the surface.

In an embodiment in which the release-treated layer A and the pressure-sensitive adhesive sheet including the silicone-based pressure-sensitive adhesive layer are used in combination, the Si amount on the surface of the release-treated layer peeled from the pressure-sensitive adhesive layer, which is measured by X-ray photoelectron spectroscopy, is preferably 1.0 atomic % or less, more preferably 0.5 atomic % or less. The Si amount is preferably equal to or less than a detection limit value. In view of the accuracy of a measurement method to be used herein, the Si amount may be 0.1 atomic % or more. The term “Si amount on the surface of the release-treated layer measured by X-ray photoelectron spectroscopy” as used herein refers to a value measured by the following method.

TABLE 1

| | |
|---|---|
| Sample | A sample was cut into a size of about 1 cm square, |
| preparation | and was held and fixed onto a sample stage. |
| Evaluation | The surface of the sample was etched by 10 nm |
| method | with an Ar ion, and was then subjected to |
| | narrow scan measurement, followed by the |
| | calculation of its element ratio (atomics). |
| Apparatus | Quantera SXM manufactured by ULVAC-PHI, Inc. |
| X-ray source | Monochromatic Al Kα |
| X-ray setting | 100 μmφ [15 kV, 25 W] |
| Photoelectron | 45° with respect to the surface of the sample |
| take-off angle | |

### C-2. Release-Treated Layer B

As described above, the release-treated layer B is a layer formed by using the composition containing the melamine resin and the long-chain alkyl-based release treatment agent. As the time period for which the long-chain alkyl-based release treatment agent is stored becomes longer, a release liner tends to become hardly peelable. The lamination of the release-treated layer B and the pressure-sensitive adhesive layer can maintain easy peelability between the pressure-sensitive adhesive layer and the release-treated layer, and a predetermined peel strength.

In the composition for forming the release-treated layer B, the long-chain alkyl-based release treatment agent is used at any appropriate content. The content of the long-chain alkyl-based release treatment agent is preferably from 0.03 part by weight to 15 parts by weight, more preferably from 0.05 part by weight to 10 parts by weight, still more preferably from 0.07 part by weight to 5 parts by weight with respect to 100 parts by weight of the melamine resin. When the content of the long-chain alkyl-based release treatment agent falls within the above-mentioned ranges, the easy peelability is exhibited, and the migration of the long-chain alkyl-based release treatment agent to the surface of the pressure-sensitive adhesive layer can be suppressed.

A material except the long-chain alkyl-based release treatment agent of the release-treated layer B, the thickness thereof, the support therefor, and the like may be set in the same manner as in the release treatment layer A.

### C-2-1. Long-Chain Alkyl-Based Release Treatment Agent

Any appropriate linear or branched long-chain alkyl group-containing compound is used as the long-chain alkyl-based release treatment agent. The number of the carbon atoms of the long-chain alkyl group of the compound is preferably 8 or more, more preferably 10 or more, still more preferably 12 or more. In addition, the number of the carbon atoms of the long-chain alkyl group is preferably 22 or less, more preferably 20 or less, still more preferably 18 or less. Examples of the above-mentioned alkyl group include an octyl group, a decyl group, a lauryl group, an octadecyl group, and a behenyl group. Examples of the long-chain alkyl group-containing compound include a long-chain alkyl group-containing polymer compound, a long-chain alkyl group-containing amine compound, a long-chain alkyl group-containing ether compound, and a long-chain alkyl group-containing quaternary ammonium salt. Of those, a long-chain alkyl group-containing polymer compound is preferred from the viewpoints of heat resistance and contamination resistance. In addition, a polymer compound having a long-chain alkyl group in a side chain thereof is more preferred because a release-treated layer that exhibits excellent easy peelability can be formed. The long-chain alkyl group-containing compounds may be used alone or in combination thereof.

The polymer compound having a long-chain alkyl group in a side chain thereof is, for example, an acrylic polymer obtained by polymerizing a monomer component containing an alkyl (meth)acrylate having an alkyl group having 8 or more carbon atoms, or a polymer obtained by causing a polymer having a reactive group and an alkyl group-containing compound that can react with the reactive group to react with each other. Examples of the above-mentioned reactive group include a hydroxy group, an amino group, a carboxy group, and an acid anhydride. A compound having such reactive group is, for example, a polyvinyl alcohol-based resin, a butyral an resin, ethylene-vinyl alcohol resin, polyethyleneimine, polyethyleneamine, a reactive group-containing polyester resin, or a reactive group-containing poly(meth)acrylic resin. A polyvinyl alcohol-based resin having a long-chain alkyl group in a side chain thereof is preferably used. In at least one embodiment of the present invention, a polyvinyl alcohol-based resin having, in a side chain thereof, an alkyl group having 8 or more carbon atoms is preferred. The term “(meth)acrylic” as used herein refers to acrylic and methacrylic.

Examples of the above-mentioned alkyl group-containing compound that can react with the reactive group to be used in the reaction with the above-mentioned polymer having the reactive group include: a long-chain alkyl group-containing isocyanate, such as octyl isocyanate, decyl isocyanate, lauryl isocyanate, octadecyl isocyanate, or behenyl isocyanate; a long-chain alkyl group-containing acid chloride, such as octyl chloride, decyl octadecyl chloride, lauryl chloride, chloride, or behenyl chloride; a long-chain alkyl group-containing amine; and a long-chain alkyl group-containing alcohol.

A commercial product may be used as the long-chain alkyl-based release treatment agent. Examples thereof include: a PEELOIL series manufactured by Lion Specialty Chemicals Co., Ltd. such as a product available under the product name “PEELOIL 1010”; and products available under the product names “ASHIO RESIN RA series” from Ashio Co., Ltd.

C-2-2. Combination with Pressure-Sensitive Adhesive Sheet

The release-treated layer B is used by being bonded to the pressure-sensitive adhesive layer of any appropriate pressure-sensitive adhesive sheet. Any appropriate pressure-sensitive adhesive may be used as a pressure-sensitive adhesive in the pressure-sensitive adhesive layer of the pressure-sensitive adhesive sheet. An active energy ray-curable pressure-sensitive adhesive may also be used as the pressure-sensitive adhesive.

### D. Production Method

The pressure-sensitive adhesive sheet for semiconductor processing with a release liner according to at least one embodiment of the present invention may be produced by any appropriate method. The pressure-sensitive adhesive sheet may be produced through, for example, the application of a composition for forming the pressure-sensitive adhesive layer to the substrate by any appropriate method. In addition, the pressure-sensitive adhesive layer formed on any appropriate support film may be transferred onto the substrate. In addition, the composition for forming the release-treated layer A or the composition for forming the release-treated layer B may be applied onto the support to form the release-treated layer. The pressure-sensitive adhesive sheet for semiconductor processing with a release liner may be obtained by laminating the produced pressure-sensitive adhesive sheet and the release-treated layer side of the laminate of the release-treated layer and the support.

When n the substrate of the pressure-sensitive adhesive sheet also functions as a support for the release-treated layer, the pressure-sensitive adhesive sheet for semiconductor processing with a release liner may be produced by: forming the release-treated layer on one surface of the substrate; then forming the pressure-sensitive adhesive layer on the other surface of the substrate; and winding the laminate in a roll shape so that the release-treated layer and the pressure-sensitive adhesive layer may be brought into contact with each other.

### E. Application

The pressure-sensitive adhesive sheet for semiconductor processing with a release liner according to at least one embodiment of the present invention is used in any appropriate semiconductor processing step, and is preferably used in a resin encapsulation step. In the resin encapsulation step, the pressure-sensitive adhesive sheet from which the release-treated layer and the support have been removed is used by being bonded to the back surface of a lead frame. In the step of bonding the pressure-sensitive adhesive sheet to the lead frame, the bonding is performed by applying any appropriate tension to the pressure-sensitive adhesive sheet. In the resin encapsulation step, the lead frame and the pressure-sensitive adhesive sheet are heated at a high temperature (of, for example, from 170 °C to 180 °C), and are then cooled. Lifting may occur between the pressure-sensitive adhesive sheet and the lead frame owing to shrinkage stress at the time of the bonding and heat shrinkage caused by the cooling after the heating. The pressure-sensitive adhesive sheet according to at least one embodiment of the present invention can suppress the contamination of the surface of the pressure-sensitive adhesive layer with a release-treated layer-derived component. Accordingly, even when the lifting occurs, the pressure-sensitive adhesive layer and the lead frame can be easily re-bonded to each other to suppress resin leakage in the resin encapsulation step.

When the pressure-sensitive adhesive sheet for semiconductor processing with a release liner is used in the resin encapsulation step, its liner peel strength is preferably 0.20 N/50 mm or less, more preferably 0.15 N/50 mm or less. In addition, its post-heating liner peel strength is preferably 0.30 N/50 mm or less, more preferably 0.20 N/50 mm or less. When the liner peel strength and the post-heating liner peel strength fall within the above-mentioned ranges, the pressure-sensitive adhesive sheet for semiconductor processing with a release liner may be suitably used in a continuous resin encapsulation step in which any appropriate tape-bonding apparatus is used.

### EXAMPLES

The present invention is specifically described below by way of Examples, but the present invention is not limited to these Examples. In addition, in Examples, “part(s)” and “%” are by weight unless otherwise stated.

### [Production Example 1] Production of Silicone-Based Pressure-Sensitive Adhesive Sheet

A polyimide film having a thickness of 25 μm (manufactured by Du Pont-Toray Co., Ltd., product name: “KAPTON 100H”) was used as a substrate. 2.5 Parts of a platinum catalyst was added to 100 parts of a silicone pressure-sensitive adhesive (manufactured by Dow Corning Toray Co., Ltd., product name: “DOWSIL SD-4587L PSA”), and the mixture was dissolved in toluene to prepare a pressure-sensitive adhesive layer-forming composition. The pressure-sensitive adhesive layer-forming composition was applied to one surface of the substrate, and was dried at 130 °C for 5 minutes to form a pressure-sensitive adhesive layer having a thickness of 6 μm. Thus, a pressure-sensitive adhesive sheet was obtained.

### [Production Example 2] Production of Acrylic Pressure-Sensitive Adhesive Sheet

A polyimide film having a thickness of 25 μm (manufactured by Du Pont-Toray Co., Ltd., product name: “KAPTON 100H”) was used as a substrate. 100 Parts of a polymer formed of butyl acrylate and acrylic acid (butyl acrylate/acrylic acid=100 parts/2 parts), 2 parts of an isocyanate-based cross-linking agent (manufactured by Mitsui Chemicals, Inc., product name: “TAKENATE D-101A”), and 1 part of an epoxy-based cross-linking agent (manufactured by Mitsubishi Gas Chemical Company, Inc., product name: “TETRAD-C”) were dissolved in toluene to prepare a pressure-sensitive adhesive layer-forming composition. The pressure-sensitive adhesive layer-forming composition was applied to one surface of the substrate, and was heated at 120 °C for 3 minutes to form a pressure-sensitive adhesive layer having a thickness of 15 μm. Thus, a pressure-sensitive adhesive sheet was obtained.

### [Production Example 3] Production of Release Liner A

100 Parts of a methylated melamine resin (manufactured by Allnex GmbH, product name: “CYMEL 303 LF”) and 0.5 part of a silicone oil (manufactured by Shin-Etsu Chemical Co., Ltd., product name: “KF-96L-2CS”) were dissolved in toluene to provide a release-treated layer-forming composition. The release-treated layer-forming composition was applied to a support (manufactured by Toray Industries, Inc., product name: “PET S-27”, thickness: 38 μm) with a bar coater so that the thickness of a release-treated layer after drying was 70 nm. Next, the resultant was dried at 130 °C for 3 minutes to provide a release liner A (release liner including a release-treated layer A).

### [Production Example 4] Production of Release Liner B

100 Parts of a methylated melamine resin (manufactured by Allnex GmbH, product name: “CYMEL 303 LF”) was dissolved in toluene, and 3 parts of a long-chain alkyl-based release treatment agent (manufactured by Ashio Co., Ltd., product name: “RA-319”) in terms of solid content was added to the solution to provide a release-treated layer-forming composition. The release-treated layer-forming composition was applied to a support (manufactured by Toray Industries, Inc., product name: “PET S-27”, thickness: 38 μm) with a bar coater so that the thickness of a release-treated layer after drying was 70 nm. Next, the resultant was dried at 130 °C for 3 minutes to provide a release liner B (release liner including a release-treated layer B).

### [Production Example 5] Production of Release Liner M1

100 Parts of a methylated melamine resin (manufactured by Allnex GmbH, product name: “CYMEL 303 LF”) was dissolved in toluene to provide a release-treated layer-forming composition. The release-treated layer-forming composition was applied to a support (manufactured by Toray Industries, Inc., product name: “PET S-27”, thickness: 38 μm) with a bar coater so that the thickness of a release-treated layer after drying was 70 nm. Next, the resultant was dried at 130 °C for 3 minutes to provide a release liner M1 (release liner including a release-treated layer M1).

### Examples 1 to 3

The pressure-sensitive adhesive layer of the pressure-sensitive adhesive sheet obtained in Production Example 1 or 2 and the release-treated layer of the release liner obtained in Production Example 3 or 4, in combination as shown in Table 2, were bonded to each other at normal temperature with a hand roller to produce a pressure-sensitive adhesive sheet with a release liner.

### Comparative Examples 1 and 2

A pressure-sensitive adhesive sheet with a release liner of each of Comparative Examples was produced in the same manner as in Examples except that the release liner M1 produced in Production Example 5 or a commercially available liner (manufactured by Unitika Ltd., product name: “UNIPEEL TR5”) was used.

TABLE 2

| | | Exam- | Exam- | Comparative |
|---|---|---|---|---|
| | | ple 1 | ple 2 | Example 1 |
| Pressure-sensitive adhesive | | Silicone-based pressure- | | |
| sheet | | sensitive adhesive sheet | | |
| Release liner | | A | B | M1 |
| Pressure-sensitive | (N/20 mm) | 0.59 | 0.62 | 0.63 |
| adhesive strength | | | | |
| Liner peel strength | (N/50 mm) | 0.03 | 0.04 | 0.33 |
| (before heating) | | | | |
| Liner peel strength | (N/50 mm) | 0.03 | 0.05 | 0.89 |
| (after heating) | | | | |
| Liner surface free | (dyn/cm) | 19.8 | — | — |
| energy | | | | |

| | | | |
|---|---|---|---|
| Presence or absence of melamine | Absent | Absent | Absent |
| in surface of pressure- | | | |
| sensitive adhesive layer | | | |
| Presence or absence of long- | — | Present | — |
| chain alkyl component in surface | | | |
| of pressure-sensitive adhesive | | | |
| layer | | | |
| Si amount (atomic %) | 0.2 | —* | —* |
| Encapsulation evaluation | No resin | No resin | Resin |
| | leakage | leakage | leakage |
| | | | is present |

| | | | Comparative |
|---|---|---|---|
| | | Example 3 | Example 2 |
| Pressure-sensitive adhesive sheet | | Acrylic pressure-sensitive | |
| | | adhesive sheet | |
| Release liner | | B | Commercially |
| | | | available |
| | | | liner |
| Pressure-sensitive | (N/20 mm) | 0.61 | 0.65 |
| adhesive strength | | | |
| Liner peel strength | (N/50 mm) | 0.07 | 0.76 |
| (before heating) | | | |
| Liner peel strength | (N/50 mm) | 0.10 | 1.20 |
| (after heating) | | | |
| Liner surface free | (dyn/cm) | — | — |
| energy | | | |

| | | |
|---|---|---|
| Presence or absence of melamine in | Absent | Absent |
| surface of pressure-sensitive | | |
| adhesive layer | | |
| Presence or absence of long-chain | Present | Present |
| alkyl component in surface of | | |
| pressure-sensitive adhesive layer | | |
| Si amount (atomic %) | — | — |
| Encapsulation evaluation | No resin | Resin leakage |
| | leakage | is present |

*Detection limit value (0.1 atomic % or less)

### <Evaluation>

The following evaluations were performed by using the pressure-sensitive adhesive sheet obtained in each of Examples and Comparative Examples. The results are shown in Table 2.

### <Pressure-Sensitive Adhesive Strength>

The pressure-sensitive adhesive sheet with a release liner obtained in each of Examples and Comparative Examples was cut into a width of 20 mm to provide a sample. The release-treated layer and the support were peeled from the sample. The surface of a SUS plate was washed with toluene, and was then washed with methanol. The SUS plate after the washing and the pressure-sensitive adhesive layer were bonded to each other, and were stored at room temperature for 30 minutes. After that, the pressure-sensitive adhesive strength of the laminate was measured by subjecting the laminate to a 180° peel test at a peel rate of 300 mm/min. The pressure-sensitive adhesive strength was measured with a universal testing machine (manufactured by A&D Company, Limited, product name: “TENSILON RTC-1210”).

### <Liner Peel Strength and Post-Heating Liner Peel Strength>

The pressure-sensitive adhesive sheet with a release liner obtained in each of Examples and Comparative Examples was cut into a width of 50 mm to provide a sample. The substrate and pressure-sensitive adhesive layer of the sample were fixed with a chuck, and the release-treated layer and the support were peeled from the sample by performing a 180° peel test at a peel rate of 300 mm/min. The resultant value was defined as a peel strength. The peel strength was measured with a universal testing machine (manufactured by A&D Company, Limited, product name: “TENSILON RTC-1210”).

The pressure-sensitive adhesive sheet with a release liner obtained in each of Examples and Comparative Examples was cut into a width of 50 mm to provide another sample. The sample was loaded into a thermostat (manufactured by Koyo Lindberg Heavy Duty Co., Ltd, product name: KLO-45M 2091), and was maintained at 60 °C for 7 days. After that, the sample was taken out of the thermostat and cooled to room temperature. After that, the substrate and pressure-sensitive adhesive layer of the sample were fixed with a chuck, and the release-treated layer and the support were peeled from the sample by performing a 180° peel test at a peel rate of 300 mm/min. The resultant value was defined as a peel strength.

### <Measurement of Surface Free Energy>

The pressure-sensitive adhesive sheet for semiconductor processing with a release liner obtained in Example 1 was stored under the conditions of 23 °C and 50% RH for 1 day. Next, the pressure-sensitive adhesive sheet for semiconductor processing with a release liner was cut into a size measuring 5 cm by 5 cm to provide a sample. The release-treated layer and pressure-sensitive adhesive layer of the sample were peeled from each other. Distilled water was dropped onto the surface of the peeled release-treated layer of the laminate of the release-treated layer and the support, and a contact angle with water was measured with a contact angle meter (manufactured by Kyowa Interface Science Co., Ltd., product name: “DM-300”) under the following conditions. Another sample was prepared, and a contact angle with methylene iodide was measured in the same manner except that methylene iodide was used instead of distilled water. The surface free energy of the surface of the release-treated layer was determined by analyzing the contact angle with analysis software (DropMaster 300 image processing-type solid-liquid interface analysis system (manufactured by Kyowa Interface Science Co., Ltd.)) attached to the contact angle meter.

### (Measurement Conditions)

Test temperature and humidity: 23 °C and 50% RH
Dropping amount: 1.5 L
Measurement time: measurement is started immediately after a droplet has reached the surface.

### <Si Amount Measurement>

The release liner was peeled from the pressure-sensitive adhesive layer of the pressure-sensitive adhesive sheet with a release liner obtained in each of Examples and Comparative Examples. Next, the release-treated surface of the release liner was subjected to measurement by X-ray photoelectron spectroscopy. Thus, the Si ratio (%) on the surface of the release-treated layer was measured. The measurement was performed under conditions shown in Table 3.

TABLE 3

| | |
|---|---|
| Sample | A sample was cut into a size of about 1 cm square, |
| preparation | and was held and fixed onto a sample stage. |
| Evaluation | The surface of the sample was etched by 10 nm |
| method | with an Ar ion, and was then subjected to |
| | narrow scan measurement, followed by the |
| | calculation of its element ratio (atomic %). |
| Apparatus | Quantera SXM manufactured by ULVAC-PHI, Inc. |
| X-ray source | Monochromatic Al Kα |
| X-ray setting | 100 μmφ [15 kV, 25 W] |
| Photoelectron | 45° with respect to the surface of the sample |
| take-off angle | |

### <FT-IR Analysis>

The release liner was peeled from the pressure-sensitive adhesive sheet with a release liner obtained in each of Examples and Comparative Examples. The presence or absence of a melamine resin in the surface of the pressure-sensitive adhesive layer after the peeling was recognized by subjecting the surface of the pressure-sensitive adhesive layer to FT-IR analysis under conditions shown in Table 4. When a melamine component is included in the surface, a peak is present at around 1, 550 cm⁻¹. When no peak was present at around 1,550 cm⁻¹, it was judged that no melamine resin was present.

With regard to the pressure-sensitive adhesive sheet with a release liner obtained in each of Examples 2 and 3, and Comparative Example 2, the presence or absence of a long-chain alkyl component in the surface of the pressure-sensitive adhesive layer was similarly recognized. When the long-chain alkyl component is included in the surface, a plurality of peaks are present at from around 2,800 cm⁻¹ to around 3,000 cm⁻¹. When a plurality of peaks were present at around 2, 850 cm⁻¹ and around 2, 925 cm⁻¹, it was judged that a long-chain alkyl-based release treatment agent-derived component was present.

TABLE 4

| | |
|---|---|
| Sample | A measurement site was pressure-bonded to an |
| preparation | ATR prism, and was subjected to the FT-IR |
| | measurement (a transferred product was also |
| | subjected to the measurement). |
| Apparatus | Apparatus: a product available under the |
| | product name “Nicolet iS50” from Thermo |
| | Fisher Scientific, Inc. |
| | ATR unit: a product available under the |
| | product name “Silver Gate” from Specac Ltd. |
| Measurement | ATR method (Ge 45°), DTGS |
| method and | |
| detector | |
| Resolution and | 4 cm⁻¹, 64 times |
| number of scans | |

### <Resin Encapsulation Evaluation>

The pressure-sensitive adhesive sheet with a release liner obtained in each of Examples and Comparative Examples was cut into a width of 50 mm. The cut pressure-sensitive adhesive sheet and one short side of a lead frame (5 mm×5 mm, 64 PIN, Cu-made lead frame) were brought into contact with each other, and were bonded to each other with a laminator under the condition of a bonding rate of 300 mm/min while the release liner was peeled. After that, the pressure-sensitive adhesive sheet protruding from both the short sides of the lead frame was cut. At the time of the bonding, the bonding was performed so that a tension to be applied to the sheet was suppressed to the extent possible. When the release liner had so high a peel strength as to be incapable of being easily peeled, the release liner was peeled from the pressure-sensitive adhesive sheet by being pulled to such an extent as not to be caught in the laminator. Next, a chip was bonded to the lead frame with a die attach film (manufactured by Nitto Denko Corporation, product name: “EM-760”). Next, the lead frame having bonded thereto the pressure-sensitive adhesive sheet was heated at 180 °C for 1 hour, and was cooled. After that, the cooled product was heated at 200 °C for 30 minutes, and was cooled. Next, the cooled product was encapsulated with an encapsulating resin (manufactured by Sumitomo Bakelite Co., Ltd., encapsulating resin product name: “SUMIKON G633 TYPE C”) through use of a mold machine (manufactured by Towa Corporation, product name: “MODEL-Y series”) under the following conditions: preheating at 175 °C for 80 seconds; an injection time of 11.5 seconds; an injection pressure of from 150 kN to 220 kN; and a cure time of 120 seconds. The clamp pressure of a mold was set to from 3 kN to 7 kN. After the encapsulation, the presence or absence of resin leakage was observed with a laser microscope (manufactured by Keyence Corporation) at a magnification of 50.

The release-treated layer of the pressure-sensitive adhesive sheet of each of Examples of the present invention had easy peelability. The easy peelability was maintained even in the evaluation after the heating, which is assumingly a physical property after long-term storage. Even when the pressure-sensitive adhesive sheet of each of Examples of the present invention was applied to the resin encapsulation test, the resin leakage was suppressed.

The pressure-sensitive adhesive sheet with a release liner according to at least one embodiment of the present invention is suitably used in a semiconductor processing step.

According to the pressure-sensitive adhesive sheet for semiconductor processing with a release liner according to at least one embodiment of the present invention, easy peelability between the pressure-sensitive adhesive layer and the release treatment layer, and a predetermined peel strength can be maintained. Further, according to the pressure-sensitive adhesive sheet for semiconductor processing with a release liner according to at least one embodiment of the present invention, the contamination of the surface of the pressure-sensitive adhesive layer after the peeling of the release liner can be suppressed.

What is claimed is:

1. A pressure-sensitive adhesive sheet for semiconductor processing with a release liner, comprising:
a pressure-sensitive adhesive sheet including a substrate and a pressure-sensitive adhesive layer;
a release-treated layer laminated on the pressure-sensitive adhesive layer; and
a support for the release-treated layer,
wherein the release-treated layer is one of (A) a layer formed by using a composition containing 0.1 part by weight to 2.0 parts by weight of a silicone-based release treatment agent with respect to 100 parts by weight of a melamine resin, or (B) a layer formed by using a composition containing a melamine resin and a long-chain alkyl-based release treatment agent.

2. The pressure-sensitive adhesive sheet for semiconductor processing with a release liner according to claim 1, wherein the silicone-based release treatment agent is a straight silicone oil.

3. The pressure-sensitive adhesive sheet for semiconductor processing with a release liner according to claim 2, wherein the pressure-sensitive adhesive layer contains a silicone-based pressure-sensitive adhesive.

4. The pressure-sensitive adhesive sheet for semiconductor processing with a release liner according to claim 3, wherein a surface of the release-treated layer peeled from the pressure-sensitive adhesive layer has a surface free energy of from 10 dyn/cm to 22.5 dyn/cm.

5. The pressure-sensitive adhesive sheet for semiconductor processing with a release liner according to claim 3, wherein a Si amount on a surface of the release-treated layer peeled from the pressure-sensitive adhesive layer, which is measured by X-ray photoelectron spectroscopy, is 1.0 atomic % or less.

6. The pressure-sensitive adhesive sheet for semiconductor processing with a release liner according to claim 1, wherein the long-chain alkyl-based release treatment agent is a long-chain alkyl group-containing compound having an alkyl group having 8 to 22 carbon atoms.

7. The pressure-sensitive adhesive sheet for semiconductor processing with a release liner according to claim 1, wherein the long-chain alkyl-based release treatment agent is a polyvinyl alcohol-based resin having a long-chain alkyl group in a side chain thereof.

8. The pressure-sensitive adhesive sheet for semiconductor processing with a release liner according to claim 1, wherein the pressure-sensitive adhesive layer from which the release-treated layer has been peeled has a pressure-sensitive adhesive strength of 1.0 N/20 mm or less.

9. The pressure-sensitive adhesive sheet for semiconductor processing with a release liner according to claim 1,
for wherein the pressure-sensitive adhesive sheet semiconductor processing with a release liner has a liner peel strength of 0.5 N/50 mm or less before being heated, and
wherein the pressure-sensitive adhesive sheet for semiconductor processing with a release liner has a liner peel strength of 1.0 N/50 mm or less after having been heated at 60 °C for 7 days.

10. The pressure-sensitive adhesive sheet for semiconductor processing with a release liner according to claim 1, wherein the pressure-sensitive adhesive sheet for semiconductor processing with a release liner is used in a resin encapsulation step.

11. The pressure-sensitive adhesive sheet for semiconductor processing with a release liner according to claim 10,
wherein the pressure-sensitive adhesive sheet for semiconductor processing with a release liner has a liner peel strength of 0.20 N/50 mm or less before being heated, and
wherein the pressure-sensitive adhesive sheet for semiconductor processing with a release liner has a liner peel strength of 0.30 N/50 mm or less after having been heated at 60 °C for 7 days.
